(19) United States
(12) Patent Application Publication
(10) Pub. No.: US 2017/0036320 A1
(43) Pub. Date: Feb. 9, 2017

(54) CMP POLISHING PAD WITH COLUMNAR STRUCTURE AND METHODS RELATED THERETO

(71) Applicant: Cabot Microelectronics Corporation, Aurora, IL (US)

(72) Inventor: Abaneshwar PRASAD, Naperville, IL (US)

(21) Appl. No.: 15/303,696

(22) PCT Filed: Apr. 17, 2015
(86) PCT No.: PCT/US2015/026393

§ 371 Date: Oct. 12, 2016

Related U.S. Application Data
(60) Provisional application No. 61/980,924, filed on Apr. 17, 2014.

(51) Int. Cl. B24B 37/26; H01L 21/321; B24B 37/24

(52) U.S. Cl. CPC B24B 37/26; B24B 37/24; H01L 21/3212

(57) ABSTRACT

The invention provides a polishing pad for chemical-mechanical polishing. The polishing pad has a substrate with two opposing surfaces and a plurality of columns projecting from at least one of the surfaces of the substrate in spaced relation to each other. The invention also provides an apparatus utilizing the polishing pad and methods for using and preparing the polishing pad.

### BACKGROUND OF THE INVENTION

Chemical-mechanical polishing (“CMP”) processes are used in the manufacturing of microelectronic devices to form flat surfaces on semiconductor wafers, field emission displays, and many other microelectronic substrates. For example, the manufacture of semiconductor devices generally involves the formation of various process layers, selective removal or patterning of portions of those layers, and deposition of yet additional process layers above the surface of a semiconducting substrate to form a semiconductor wafer. The process layers can include, by way of example, insulation layers, gate oxide layers, conductive layers, and layers of metal or glass, etc. It is generally desirable in certain steps of the wafer process that the uppermost surface of the process layers be planar, i.e., flat, for the deposition of subsequent layers. CMP is used to planarize process layers wherein a deposited material, such as a conductive or insulating material, is polished to planarize the wafer for subsequent process steps.

In a typical CMP process, a wafer is mounted upside down on a carrier in a CMP tool. A force pushes the carrier and the wafer downward toward a polishing pad. The carrier and the wafer are rotated above the rotating polishing pad on the CMP tool's polishing table. A polishing composition (also referred to as a polishing slurry) is introduced between the rotating wafer and the rotating polishing pad during the polishing process. The polishing composition typically contains a chemical that interacts with or dissolves portions of the uppermost wafer layer(s) and an abrasive material that physically removes portions of the layer(s). The wafer and the polishing pad can be rotated in the same direction or in opposite directions, whichever is desirable for the particular polishing process being carried out. The carrier also can oscillate across the polishing pad on the polishing table.

Polishing pads made of harder materials exhibit high removal rates and have long useful pad life, but tend to produce numerous scratches on substrates being polished. Polishing pads made of softer materials may exhibit less scratching of substrates than polishing pads made of harder materials, but tend to exhibit lower removal rates and have shorter useful pad life. Accordingly, there remains a need in the art for polishing pads that provide effective removal rates and have extended pad life, and also produce limited defectivity (e.g., scratching) of substrates.

### BRIEF SUMMARY OF THE INVENTION

In one aspect, the invention provides a polishing pad for chemical-mechanical polishing. The polishing pad comprises a pad substrate with two opposing surfaces and a plurality of columns projecting from at least one of the surfaces of the pad substrate in spaced relation to each other. Each of the columns has a body with a proximate portion having an end that affixes to the pad substrate and an opposite distal portion suitable for contacting a workpiece. The pad substrate has a higher average hardness than the average hardness of the distal portion.

In another aspect, the invention provides a chemical-mechanical polishing apparatus. The chemical-mechanical polishing apparatus comprises (a) a platen that rotates; (b) a polishing pad; and (c) a carrier that holds a workpiece to be polished by contacting the rotating polishing pad. The polishing pad comprises a substrate with two opposing surfaces and a plurality of columns projecting from at least one of the surfaces of the substrate in spaced relation to each other. Each of the columns has a body with a proximate portion having an end that affixes to the substrate and an opposite distal portion suitable for contacting a workpiece. The proximate portion and the substrate have a higher average hardness than the average hardness of the distal portion. In some embodiments, the chemical-mechanical polishing apparatus further comprises (d) means for delivering a chemical-mechanical polishing composition between the polishing pad and the workpiece.

In another aspect, the invention provides a method of polishing a workpiece. The method of polishing a workpiece comprises (i) providing a polishing pad; (ii) contacting the workpiece with the polishing pad; and (iii) moving the polishing pad relative to the workpiece to abrade the workpiece and thereby polish the workpiece. The polishing pad comprises a substrate with two opposing surfaces and a plurality of columns projecting from at least one of the surfaces of the substrate in spaced relation to each other. Each of the columns has a body with a proximate portion having an end that affixes to the substrate and an opposite distal portion suitable for contacting a workpiece. The proximate portion and the substrate have a higher average hardness than the average hardness of the distal portion. In some embodiments, the method of polishing a workpiece further comprises providing a chemical-mechanical polishing composition between the polishing pad and the workpiece, contacting the workpiece with the polishing pad with the polishing composition therebetween, and moving the polishing pad relative to the workpiece with the polishing composition therebetween to abrade the workpiece and thereby polish the workpiece.

In another aspect, the invention provides a method of preparing a polishing pad. The method of preparing a polishing pad comprises providing a substrate; providing a plurality of columns, each column having a body with a proximate portion having an end that affixes to the substrate and an opposite distal portion suitable for contacting a workpiece, and wherein the proximate portion and the substrate have a higher average hardness than the average hardness of the distal portion; and attaching the columns to the substrate in a spaced relation.

### BRIEF DESCRIPTION OF THE SEVERAL VIEWS OF THE DRAWING(S)

FIG. 1A is a perspective view of a chemical-mechanical polishing pad comprising a substrate and a plurality of columns projecting from the substrate, in accordance with embodiments of the invention.

FIG. 1B is a detail illustrating one of the columns relative to the substrate of the polishing pad, taken from rectangle B of FIG. 1A, in accordance with embodiments of the invention.

FIG. 2 is a schematic cross-sectional side view of a composite pad structure, in accordance with embodiments of the invention, which is displayed with x/y axes for measurement purposes, where the x-axis represents the trench and column width in microns and the y-axis represents the composite pad thickness and trench depth/height in microns.

FIGS. 3A-3D depict examples of polishing pads, in accordance with embodiments of the invention, that illustrate various shapes and orientations of columns projecting from a substrate.

FIGS. 4A-4D are scanning electron micrographs (SEM) at 24 times magnification (FIGS. 4A and 4C) or 100 times magnification (FIGS. 4B and 4D), illustrating columns projecting from a polymer substrate of a polishing pad prepared by a printing technique, in accordance with embodiments of the invention.

FIG. 5 is a photograph depicting a polishing pad that shows an example of a pattern of large columns cast onto a substrate in the form of a 0.05 mm (2 mils) polyethylene terephthalate (“PET”) film, with the following column definition: 2 mm column diameter, 1.06 mm column height, 5 mm column pitch, 40% void volume, 11 column/linear inch.

FIG. 6 is a photograph depicting a polishing pad that shows an example of a pattern of columns cast onto a substrate in the form of a polycarbonate laminate, prepared with double coated polyester film tape 442F commercially available from 3M (St. Paul, Minn.), illustrating a pattern of fine columns.

FIG. 7 is a photograph depicting a polishing pad that shows an example of a pattern of columns cast onto a substrate in the form of a polycarbonate laminated with double coated polyester film tape (3M 442F), illustrating a pattern of large columns.

FIG. 8 is a graph illustrating the results when blanket wafers containing copper or silicon oxide, respectively, are polished using a polishing pad in accordance with the invention in comparison with a conventional pad commercially identified as Fujibo H7000, available from Marubeni America Corp. (Sunnyvale, Calif.), as described in Example 3. The graph plots the removal rate (y-axis) vs. the number of wafers polished (x-axis).

### DETAILED DESCRIPTION OF THE INVENTION

Embodiments of the invention provide a polishing pad for chemical-mechanical polishing. The polishing pad comprises a pad substrate having opposing top and bottom surfaces. A plurality of columns project from the top surface of the pad substrate in spaced relation to each other. Each of the columns has a body with a proximate portion having an end that affixes to the pad substrate and an opposite distal portion suitable for contacting a workpiece, such as a semiconductor wafer. The pad substrate has a higher average hardness than the average hardness of the distal portion of at least some of the columns. In preferred embodiments, the proximate portions of the columns also have a higher average hardness than that which is exhibited by the distal portions.

Surprisingly and unexpectedly, the design of the inventive polishing pad optimizes hardness variation in the polishing pad to maximize polishing performance and to extend the life of the polishing pad in some embodiments. The polishing pad design of the invention also allows for decoupling the movement of the columns from the pad substrate. In particular, the harder pad substrate has an average hardness sufficient to firmly adhere the pad to the workpiece while the distal portions of the columns, which contact the workpiece being polished with the aid of asperities as known in the art, are relatively softer. As a result, polishing pads according to embodiments of the invention provide effective removal rates and preferably do not generate excessive defectivity in operation. In embodiments of the invention, the pad substrate imparts sufficient average hardness and strength to achieve good planarization efficiency while the relatively softer distal portions of the columns facilitate reduced defectivity in operation.

The inventive polishing pad can be used with any suitable polishing composition known in the art in the chemical-mechanical polishing of a workpiece, e.g., a semiconductor wafer. In some embodiments, it has been found that use of polishing composition with reduced abrasive particle content (e.g., about 0.2 wt. % solids or less, such as about 0.1 wt. % or less, 0.05 wt. % or less, 0.01 wt. % or less, etc.) or no content of abrasive particles is particularly advantageous. The use of such low particle or zero particle polishing compositions has been found to advantageously reduce the number of defects that may result during chemical-mechanical polishing with the polishing pad in accordance with embodiments of the invention.

The polishing pad of the invention can be applied at any suitable downforce (DF) or platen speed (as discussed below) during a typical polishing period, e.g, about 15 seconds, about 30 seconds, about 45 seconds, about one minute, about 90 seconds, about two minutes, etc. It will be understood that downforce and platen speed normally have a direct relationship with removal rate of silicon oxide or metal, such as copper or the like, during polishing. Whereas conventional polishing pads are designed to be used with a relatively high downforce (e.g., at least about 7 psi (48 kPa) or 8 psi (55 kPa)), embodiments of the invention advantageously can be used with reduced downforce, e.g., about 4 psi (27 kPa) or less, such as from about 3 psi (20.25 kPa) to about 3.5 psi (23.62 kPa), from about 2 psi (13.50 kPa) to about 2.5 psi (16.87 kPa), or from about 1 psi (6.75 kPa) to about 1.5 psi (10.12 kPa). Similarly, whereas conventional polishing pads are designed to be used with a relatively high platen speed (e.g., at least about 100-110 rpm), some embodiments of the invention advantageously can be used with reduced platen speed such as from about 60 rpm to about 90 rpm, e.g., from about 60 rpm to about 80 rpm, from about 60 rpm to about 70 rpm, from about 70 rpm to about 90 rpm, from about 70 rpm to about 80 rpm, or from about 80 rpm to about 90 rpm. The use of such reduced platen speeds have a positive effect on reducing shearing exposure for the material being polished. Thus, the use of such reduced downforce and platen speed have also been found to be advantageous in reducing the number of defects that result during use in polishing a workpiece such as a semiconductor wafer.

Thus, in use, embodiments of the polishing pad of the invention surprisingly and unexpectedly realize a desired combination of planarization efficiency and low defectivity, both of which are important parameters in CMP processes, and often in conflict with one another in conventional systems. Preferably, the polishing pad of the invention results in a reduced number of defects, e.g., scratches, which in turn increases wafer yield during manufacture since less wafers need to be discarded due to concerns over the proper functioning of the microelectronic devices on the wafer. At the same time, polishing pads in accordance with embodiments of the invention surprisingly can be polished with good planarization efficiency. In this respect, the planarization efficiency is defined as the unitless formula of one minus the ratio of removal rate for the bottom structure divided by the removal rate for the top structure. See, e.g., Y. Li, Microelectronics Applications of Chemical Mechanical Planarization, J. Wiley & Sons, 2008, p. 517. By tailoring regions of hardness (and hence strength) in the polishing pad, embodiments of the invention surprisingly and unexpectedly achieve the desired combination of planarization efficiency with low defectivity. The planarization efficiency achieved in accordance with the invention will vary depending on application. In preferred embodiments, the planarization efficiency is at least about 70%, e.g., at least about 80%, at least about 90%, at least about 95%, at least about 99%, etc.

The polishing pad of the invention has applicability in polishing a wide variety of semiconductor wafers used in fabrication of integrated circuits and other microdevices. Such wafers can be of conventional node configuration in some embodiments, e.g., technology nodes of 65 nm or less, 45 nm or less, 32 nm or less, etc. However, in some embodiments, the inventive polishing pad is particularly suited for advanced node applications (e.g., technology nodes of 28 nm or less, 22 nm or less, 18 nm or less, 16 nm or less, 14 nm or less, etc.). It will be understood that, as node technology becomes more advanced, the absence of defectivity in planarization technology becomes more important because the effects of each scratch have more of an impact as the relative size of features on the wafer gets smaller. Because of the significant advancement over the art that the polishing pad of the invention provides, as compared with conventional polishing pads, the level of defectivity is reduced and more advanced node polishing can be achieved with fewer scratches and less delamination (e.g., of low dielectric (k) materials) on the workpiece in accordance with embodiments of the invention. As such, embodiments of the polishing pad of the invention can accommodate more precise planarization of wafers with smaller features with lower absolute removal rate, lower defectivity, and improved planarization efficiency. However, as noted, the polishing pad of the invention is not limited to use with advanced node wafers and can be used to polish other workpieces as desired.

The polishing pad of the invention can be used to polish a workpiece containing material exhibiting any suitable dielectric constant relative to silicon dioxide, such as a low dielectric constant of about 3.5 or less (e.g., about 3 or less, about 2.5 or less, about 2 or less, about 1.5 or less, or about 1 or less). Alternatively, or in addition, the organic polymer film can have a dielectric constant of about 1 or more (e.g., about 1.5 or more, about 2 or more, about 2.5 or more, about 3 or more, or about 3.5 or more). Thus, the workpiece can contain material having a dielectric constant bounded by any two of the foregoing endpoints. For example, the workpiece can contain a material having a dielectric constant between about 1 and about 3.5 (e.g., between about 2 and about 3, between about 2 and about 3.5, between about 2.5 and about 3, or between about 2.5 and about 3.5).

The pad substrate can have any suitable configuration, shape, and dimensions. For example, the pad substrate can be substantially planar. The pad substrate can be configured relative to the columns in a manner that the columns have a longitudinal axis and an axis transverse to the longitudinal axis. For example, a cross-section of a plane along the transverse axis of the columns can form a polygonal (e.g., a triangle, quadrilateral, pentagon, hexagon, heptagon, octagon, etc.), circular, or other suitable perimeter shape in some embodiments.

The pad substrate can have any suitable size, i.e., distance between ends or diameter, such as at least about 25 cm (10 inch). For example, in some embodiments, the size of the pad substrate can be from about 25 cm to about 140 cm (55 inch), e.g., from about 25 cm to about 120 cm (47 inch), from about 25 cm to about 100 cm (39 inch), from about 25 cm to about 75 cm (29.5 inch), from about 25 cm to about 50 cm (19.5 inch), from about 25 cm (10 inch) to about 51 cm (20 inch), from about 50 cm to about 140 cm, from about 50 cm to about 120 cm, from about 50 cm to about 100 cm, from about 50 cm to about 75 cm, from about 57 cm (22.5 inch) to about 61 cm (24 inch), from about 75 cm to about 140 cm, from about 75 cm to about 120 cm, from about 75 cm to about 100 cm, from about 76 cm (30 inch) to about 102 cm (40 inch), from about 100 cm to about 140 cm, from about 100 cm to about 120 cm, from about 107 cm (42 inch) to about 140 cm, or from about 120 cm to about 140 cm. For example, in some embodiments, the pad substrate can have a size of about 140 cm.

Any suitable thickness for the pad substrate can be used. In some embodiments, the pad substrate has a thickness from about 0.025 cm to about 1 cm, such as from about 0.025 cm to about 0.05 cm, e.g., from about 0.025 cm to about 0.10 cm, from about 0.05 cm to about 0.25 cm, from about 0.25 cm to about 0.5 cm, or from about 0.5 cm to about 0.75 cm. The pad substrate can be in the form of one layer or a multi-layer composite as discussed below.

The pad substrate can be formed of any suitable material so that the pad substrate is typically harder than the distal portion of the columns. For example, the pad substrate can be formed of suitable thermoset, thermoplastic, or metallic material. In some embodiments, the pad substrate can be a porous foamed or non-foamed (solid) thermoplastic, such as, for example, polycarbonate, polyethylene terephthalate (PET), or biaxially-oriented polyethylene terephthalate (e.g., MYLAR™, commercially available from DuPont Teijin Films, London, UK), polytetrafluoroethylene (e.g., TEFLON™, commercially available from DuPont Company, Wilmington, Del.), nylon, acrylics, polyvinyl chloride (PVC), high glass transition temperature (e.g., from about 90° C. (195° F.) to about 200° C. (390° F.), such as from about 100° C. (212° F.) to about 180° C. (356° F.)) polystyrene based copolymers and terpolymers (such as styrene-maleic anhydride co-polymers or styrene-maleic anhydride-phenylmaleicimide ter-polymer, etc.), polyolefins, such as polyethylene (PE), polypropylene (PP), polyether ether ketone (PEEK), Poly(ether imide) (PEI), poly(acetals), etc.

The pad substrate can be formed of one layer or multiple layers to form a composite pad substrate in some embodiments. For example, in some embodiments, the pad substrate comprises a base layer formed of softer material than an overlying layer adjacent to the columns (e.g., from which the columns project). In such embodiments, the softer base layer of the substrate is more compressible and provides a better conformal polishing surface. In other embodiments, the base layer is harder than the overlying layer adjacent to the columns so that the harder base layer provides mechanical support to the top overlying softer layer. In some embodiments, the multiple layers can be of similar average hardness (e.g., within an average hardness range of about 10% of each other, such as, within a range of about 7%, within a range of about 5%, within a range of about 4%, within a range of about 3%, within a range of about 2%, within a range of about 1%, within a range of about 0.5%, or within a range of about 0.1%). Each layer can have suitable average hardness values as described herein for the pad substrate, such as a Shore D hardness of about 25 to about 85 as measured according to ASTM D2240-10, with any desired variation in average hardness between layers as discussed above.

If desired, the pad substrate optionally can be formed to define at least one trench therein to receive the proximate end of at least one column to facilitate attachment thereof. In some embodiments, the number of trenches and the number of columns correspond. To create such trenches, it will be understood that holes can be drilled or otherwise formed therein in any shape or size to facilitate deposition of the columns, e.g., in a similar configuration as the perimeter shape of a cross section of the columns to optimize or facilitate receiving the columns in the trenches. For example, in the case of columns having a square cross section, the trenches would also form a square shape in some embodiments. The trenches can have any suitable dimensions. For example, the trenches can be formed to define a depth that preferably receives a sufficient portion of the proximate portion of the columns to effectively affix the columns to the substrate. For example, the depth of the trenches can be characterized as less than total thickness of the pad substrate, e.g., from about 250 microns (10 mils) to about 1000 microns (40 mils) while retaining sufficient structural integrity beneath the trenches. The trenches can be formed to define any suitable length and width. For example, in some embodiments, the trenches can be configured to correspond with the perimeter shape of the columns, such as to allow for proper fitting, e.g., a snap fit. In some embodiments, a small gap or space around the columns can also be suitable for polishing.

In some embodiments, the trenches contain a relatively softer material disposed around the columns, e.g., having an average Shore A hardness of from about 10 to about 95 as measured according to ASTM D2240-10. Generally, the softer material has a softness similar to or within the ranges provided herein for the distal portions of the columns and can be composed of similar materials as described herein for the distal portions of the columns. The soft material can be deposited in the trenches before, during, or after inserting the columns. In some embodiments, use of the relatively soft material is beneficial in maximizing the relative surface area of softer regions of the pad to reduce defects without significantly compromising planarization efficiency of the overall pad structure. In such embodiments, effective planarization efficiency is still preferably achieved by the remaining hard columns projecting from the trenches.

The trenches can be filled with relatively soft material by any suitable method. For example, the trenches can be filled by chemical vapor deposition, physical vapor deposition, liquid fill followed by x-linking and/or solidification, or by hot pressing, embossing, and/or thermoforming following the deposition of relatively soft material in the form of a thin layer (e.g., having a thickness of from about 12 microns (0.5 mils) to about 1000 microns (40 mils), such as from about 25 microns (1 mils) to about 500 microns (20 mils)) of polymer on top of the columns, which in some embodiments will leave a layer of relatively soft pad material on top of the columns that can either be completely removed, e.g., by a buffing process, or partially removed such that a relatively soft surface layer remains.

Since the pad substrate is a relatively harder material than at least the distal portion of the columns, the pad substrate has an average Shore D hardness of from about 20 as measured according to ASTM D2240-10 to an average Rockwell M hardness of about 150 as measured according to ASTM D785-08, such as from about 20 D to about 50 D, e.g., from about 20 D to about 80 D, from about 50 D to about 88 D, from about 50 D to about 100 M, from about 50 D to about 110 M, from about 88 D to about 120 M, or from about 88 D to about 150 M.

Advantageously, the pad substrate can be substantially free of grooves in some embodiments. This can be a significant advantage in some embodiments of the invention over conventional polishing pads that typically include grooves, e.g., from about 15 mils (0.38 mm) to about 45 mils (1.14 mm) deep to disperse the polishing composition underneath the substrate being polished (e.g., a semiconductor wafer). In accordance with the invention, it has been found that the use of grooves is not fully satisfactory because the life of the polishing pad will shorten as the groove wears off after use. Moreover, as the grooves start to wear, debris can be trapped, which will give rise to defects in the substrate being polished. Thus, it is a significant advantage that the novel and unique design of the inventive polishing pad allows for avoiding the use of such grooves since the polishing composition can pass in between columns. As such, a polishing pad in accordance with embodiments of the invention can exhibit longer pad life. Whereas conventional pads typically are discarded after 400-500 uses, the inventive pad can be used to polish, in some embodiments, at least about 500 wafers, e.g., at least about 750 wafers or even at least about 1,000 wafers (such as from about 500 to about 1,500 wafers, from about 600 to about 1,400 wafers, from about 700 to about 1,300 wafers, from about 800 to about 1,250 wafers, from about 1,000 to about 1,200 wafers, etc.).

An aspect ratio is defined for the thickness of the pad substrate relative to the diameter of the pad substrate. In some embodiments, the aspect ratio of the thickness of the pad substrate to the diameter of the pad substrate is at least about 1, such as from about 0.0001 to about 0.9, e.g., from about 0.0001 to about 0.7, from about 0.0001 to about 0.5, from about 0.0001 to about 0.3, from about 0.0001 to about 0.15, from about 0.0001 to about 0.1, from about 0.0001 to about 0.05, from about 0.0001 to about 0.04, from about 0.0001 to about 0.025, from about 0.0001 to about 0.01, from about 0.007 to about 0.9, from about 0.007 to about 0.7, from about 0.007 to about 0.5, from about 0.007 to about 0.3, from about 0.00710 about 0.15, from about 0.007 to about 0.1, from about 0.007 to about 0.05, from about 0.007 to about 0.04, from about 0.007 to about 0.025, from about 0.007 to about 0.01, from about 0.01 to about 0.9, from about 0.01 to about 0.7, from about 0.01 to about 0.5, from about 0.01 to about 0.3, from about 0.01 to about 0.15, from about 0.01 to about 0.1, from about 0.01 to about 0.05, from about 0.01 to about 0.04, or from about 0.01 to about 0.025.

The columns of the polishing pad can be spaced on the substrate in any suitable manner. In some embodiments, the columns can be spaced substantially uniformly. In other embodiments, the columns can be spaced randomly. Any suitable population density of columns can be used. For example, in some embodiments, the polishing pad can include from about 4 columns to about 2,500 columns per cm² of the substrate surface, such as from about 4 to about 2,000, e.g., from about 4 to about 1,000, from about 4 to about 500, from about 4 to about 100, from about 4 to about 75, from about 4 to about 50, from about 4 to about 25, from about 4 to about 10, from about 10 to about 2,000, from about 10 to about 1500, from about 10 to about 1,000, from about 10 to about 750, from about 10 to about 500, from about 10 to about 250, from about 10 to about 100, from about 10 to about 50, from about 10 to about 25, from about 25 to about 2,500, from about 25 to about 2,000, from about 25 to about 1,500, from about 25 to about 1,000, from about 25 to about 750, from about 25 to about 500, from about 25 to about 250, from about 25 to about 100, from about 25 to about 50, from about 50 to about 2,500, from about 50 to about 2,000, from about 50 to about 1,500, from about 50 to about 1,000, from about 50 to about 750, from about 50 to about 500, from about 50 to about 250, from about 50 to about 100, from about 100 to about 2,000, from about 100 to about 1,500, from about 100 to about 1,000, from about 100 to about 750, from about 100 to about 500, from about 100 to about 250, from about 200 to about 2,000, from about 200 to about 1,500, from about 200 to about 1,000, from about 200 to about 750, from about 200 to about 500, from about 200 to about 250, from about 500 to about 2,000, from about 500 to about 1,500, from about 50010 about 1,000, from about 500 to about 750, from about 750 to about 2,500, from about 750 to about 2,000, from about 750 to about 1,500, from about 750 to about 1,000, from about 1,000 to about 2,500, from about 1,000 to about 2,000, or from about 1,000 to about 1,500.

The columns can have any suitable size and dimensions. The shape of the columns can vary or be the same on any particular polishing pad. For example, at least some (e.g., all) of the columns can be cylindrical in some embodiments. In some embodiments, some or all of the columns can form a polygonal cross-section, e.g., in the shape of a triangle, quadrilateral, pentagon, hexagon, heptagon, octagon, etc. The columns can have varying height and diameter or the columns can be substantially similar (e.g., within a size range of 5% of each other, within a range of 4% of each other, within a range of 3% of each other, within a range of 2% of each other, or within a range of 1% of each other).

For example, in some embodiments, the columns can be formed to define a length and width effective to achieve a desired degree of planarization efficiency and/or to reduce or minimize wafer scratch count, e.g., dimensions in any direction from about 10 microns (0.4 mils) to about 1500 microns (59 mils), such as from about 100 microns (4 mils) to about 1000 microns (40 mils).

The average height of the columns, in some embodiments, can be, for example, from about 125 μM (4.9 mils) to about 1,500 μm (59 mils), such as from about 250 μm (10 mils) to about 1,525 μm (60 mils), from about 350 μm (14 mils) to about 1,200 μm (47 mils), from about 500 μm (20 mils) to about 1,000 μm (39 mils), from about 500 μm (20 mils) to about 800 μm (31 mils), from about 600 μm (24 mils) to about 750 μm (e.g., from about 635 μm (25 mils) to about 711 μm (28 mils)).

The columns can have any suitable average diameter. In some embodiments, the average diameter of the columns can be from about 3 μm to about 1 mm, such as from about 3 μm to about 1,000 μm, e.g., from about 5 μm to about 500 μm, from about 5 μm to about 250 μm, from about 5 μm to about 200 μm, from about 5 μm to about 150 μm, from about 5 μm to about 100 μm, from about 5 μm to about 50 μm, 8 μm to about 1,000 μm, from about 8 μm to about 500 μm, from about 8 μm to about 250 μm, from about 8 μm to about 200 μm, from about 8 μm to about 150 μm, from about 8 μm to about 100 μm, from about 8 μm to about 50 μm, 10 μm to about 1,000 μm, from about 10 μm to about 500 μm, from about 10 μm to about 250 μm, from about 10 μm to about 200 μm, from about 10 μm to about 150 μm, from about 10 μm to about 100 μm, or from about 10 μm to about 50 μm.

The columns can be formed of any suitable material. For example, the columns can be formed from rubber, thermoset, thermoplastic material, or any combination thereof. In some embodiments, the columns are formed from fibrous material. The columns, for example, can be formed from elastic rubber, aramid fiber, cross-linked polyurethane foamed materials or non-foamed materials, nylons, acrylates, UV cross-linkable polymers, PET, PEBAX(poly-b-amide copolymers), PC, poly(vinylalcohol), styrenic polymers and rubber etc., or any combination thereof. Such materials can have varying average hardness and can be made to be suitably soft in the distal portions as described herein. Hardness of such materials can be adjusted by, e.g., introducing varying degrees of percent porosity (defined as the ratio of the densities of a porous column to that of a non-porous column), altering hard or soft segment ratio in polymers like TPU, by changing the degree of cross-linking (for polymers that can be cross-linked), varying the degree of crystallinity, or by depositing copolymers, as one of ordinary skill in the art will appreciate. For foamed materials, any suitable foam density can be used, e.g., between about 0.1 g/cc (90% density reduction) to about 1.5 g/cc (1% density reduction), such as from about 0.2 g/cc to about 1.2 g/cc, from about 0.3 g/cc to about 1.1 g/cc, from about 0.35 g/cc to about 0.99 g/cc, or from about 0.35 g/cc to about 0.90 g/cc. In some embodiments, the columns can exhibit a storage modulus (E′) at 25° C. of below about 2,500 MPa, such as from about 1 MPa to about 2,500 MPa, e.g., from about 10 MPa to about 2,000 MPa, from about 15 MPa to about 1500 MPa, from about 20 MPa to about 1200 MPa, or from about 20 MPa to about 1000 MPa. The column aspect ratio of diameter to height can be from about 0.0125 to about 1 in some embodiments, when, for example, the minimum column height is about 0.0254 mm (1 mils), the maximum column height is about 2.03 mm (80 mils), the minimum column diameter is about 0.0254 mm (1 mils), and the maximum column diameter is about 2.03 mm (80 mils).

The distal portion of the column typically will be about 40% or less of the total height of the column, such as from about 30% or less, about 25% or less, or about 20% or less of the total height of the column. Thus, the distal portion of the column typically will be from about 5% to about 40%, e.g., from about 5% to about 30%, from about 10% to about 30%, or from about 15% to about 25% of the total height of the column. The amount of distal portion of the column will be less than 60% of total amount of column.

If desired, the distal portions of the columns can include pores. The pores can be interconnected or closed in various embodiments. In some embodiments, the distal portions of the columns have an average void volume of from about 5% to about 90% of the total volume of the distal portion. In some embodiments, the average void volume is designed to be between 10% and 85%. For example, in some embodiments, the average void volume is from about 10% to about 85%, e.g., from about 10% to about 80%, from about 10% to about 75%, from about 15% to about 75%, or from about 20% to about 65%. The pores can have any suitable dimensions. For example, the pores in the distal portions of the columns can have an average diameter of about 150 microns or less, such as from about 0.1 μm to about 150 μm, e.g., from about 1 μm to about 120 μm, from about 10 μm to about 100 μm, from about 15 μm to about μm 1,000, or from about 20 μm to about 80 μm.

In some embodiments, the columns exhibit a glass transition temperature from about −80° C. to about 250° C., such as from about −60° C. to about 250° C., e.g., from about −60° C. to about 200° C., from about −50° C. to about 180° C., from about −50° C. to about 150° C., or from about −40° C. to about 150° C., by using dynamic mechanical analyzer (DMA) tan δ peak value. Advantageously, the polishing pad including such columns in accordance with embodiments of the invention exhibits good shear abrasion resistance, thereby resulting in longer pad life as determined by the area under the tan δ curve and by pad cut rate data. In some embodiments, the polishing pad has a compression force deflection (also known as CFD or CLD) at 25% deflection from about 1 psi (6.80 kPa) to about 500 psi (3,450 kPa), such as from about 2 psi (13.6 kPa) to about 450 psi (3,060 kPa), e.g., from about 5 psi (34.5 kPa) to about 400 psi (2720 kPa), from about 5 psi (34.5 kPa) to about 300 psi (2040, kPa), from about 5 psi (34.5 kPa) to about 200 psi (1,360 kPa), or from about 10 psi (69 kPa) to about 100 psi (680 kPa). In some embodiments, the polishing pad has a percentage elongation at break from about 10% to about 800%, such as from about 20% to about 750%, e.g., from about 30% to about 700%, from about 40% to about 700%, from about 40% to about 600%, or from about 40% to about 500%. In some embodiments, the polishing pad has a percentage compression set at 70° C. and 34.5 kPa (5 psi) of less than about 20%, such as from about 1% to about 20%, e.g., from about 2% to about 15%, from about 3% to about 15%, from about 4% to about 15%, or from about 5% to about 10%.

The pad substrate has a higher average hardness than the average hardness of the distal portion. The columns can have substantially uniform average hardness in some embodiments or varying average hardness. For example, the proximate portion can have a higher average hardness than the average hardness of the distal portion. Desirably, in some embodiments, the distal portions of the columns have an average Shore A hardness of from about 10 to about 90 (e.g., from about 15 to about 70, from about 20 to about 60, from about 30 to about 50, etc.) as measured according to ASTM D2240-10. In some embodiments, the proximate portion of at least some of the columns have an average Shore D hardness of from about 10 to about 90 as measured according to ASTM D2240-10, such as from about 10 to about 80, e.g., from about 10 to about 75, from about 10 to about 75, from about 15 to about 72, or from about 15 to about 70. In some embodiments, the proximate portions of the columns and the pad substrate can have the same or similar average hardness (e.g., within an average hardness range of about 10% of each other, such as, within a range of about 7%, within a range of about 5%, within a range of about 4%, within a range of about 3%, within a range of about 2%, within a range of about 1%, within a range of about 0.5%, or within a range of about 0.1%). Thus in some embodiments, the proximate portion of the columns can have an average hardness from about 20 Shore D to about 150 Rockwell M.

The hardness of each portion of the columns can be manipulated within these ranges to achieve a higher average hardness for the proximate portion than for the distal portion. In some embodiments, at least one column (e.g., all of the columns) has varying average hardness ranging from a Shore A hardness of about 10 to a Shore D hardness of about 90, both as measured according to ASTM D2240-10. The varying hardness can be in any suitable arrangement. For example, the varying hardness can be in a random pattern, or in a pre-selected pattern as desired. The proximate portion of one or more columns and the pad substrate can individually or both have an average hardness that is greater than 1 times the average hardness of the distal portion of one or more columns, in some embodiments, e.g., from about 1.1 times to about 50 times, from about 1.1 times to about 40 times, from about 1.1 times to about 30 times, from about 1.1 times to about 25 times, from about 1.1 times to about 15 times, from about 1.1 times to about 10, from about 1.1 times to about 5 times, from about 1.1 times to about 2 times, from about 1.25 times to about 50 times, from about 1.25 times to about 25 times, from about 1.25 times to about 10 times, from about 1.25 times to about 5 times, from about 1.25 times to about 2 times, from about 1.5 times to about 50 times, from about 1.5 times to about 25 times, from about 1.5 times to about 10, from about 1.5 times to about 5 times, from about 1.5 times to about 2 times, from about 2 times to about 50 times, from about 2 times to about 40 times, from about 2 times to about 30 times, from about 2 times to about 25 times, from about 2 times to about 15 times, from about 2 times to about 10 times, from about 2 times to about 5 times, from about 5 times to about 50 times, from about 5 times to about 25 times, from about 5 times to about 10 times, from about 10 times to about 50 times, from about 10 times to about 25 times, from about 20 times to about 50 times, from about 20 times to about 40 times, or from about 20 times to about 30 times.

In some embodiments, the columns can be formed of a unitary body, e.g., having uniform average hardness that is lower than the average hardness of the pad substrate for ease of manufacture. The pad substrate and columns of uniform or varying hardness can be formed by any suitable method. The pad substrate, for example, can be made by extrusion methods, casting, calendaring, injection molding, etc. In some embodiments, the columns will be made by techniques such as screen printing, 3D printing, or reactive injection molding (RIM) casting onto the substrate. Individual column pieces can be welded onto the pad substrate in some embodiments.

One or more (e.g., all) of the columns can include a film, which may be continuous or discontinuous (e.g., formed from droplets), of material over the distal portion in some embodiments. If desired, the film can include pores, while in other embodiments the film is non-porous. The film can include holes to facilitate polishing composition flow in some embodiments. The holes can be formed in any suitable manner, such as by use of needle punch or laser engraving. The film can have any suitable shape and configuration. For example, the film can have a thickness of from about 25 μm to about 1,000 μm, e.g., from about 25 μm to about 750 μm, from about 25 μm to about 500 μm, from about 25 μm to about 425 μm, from about 25 μm to about 300 μm, from about 25 μm to about 125 μm, from about 25 μm to about 75 μm, from about 25 μm to about 50 μm, from about 50 μm to about 1,000 μm, from about 50 μm to about 750 μm, from about 50 μm to about 500 μm, from about 50 μm to about 425 μm, from about 50 μm to about 300 μm, from about 50 μm to about 125 μm, from about 50 μm to about 75 μm, from about 75 μm to about 1,000 μm, from about 75 μm to about 750 μm, from about 75 μm to about 500 μm, from about 75 μm to about 425 μm, from about 75 μm to about 300 μm, from about 75 μm to about 125 μm, from about 125 μm to about 1,000 μm, from about 125 μm to about 750 μm, from about 125 μm to about 500 μm, from about 125 μm to about 425 μm, from about 125 μm to about 300 μm, from about 300 μm to about 1,000 μm, from about 300 μm to about 750 μm, from about 300 μm to about 500 μm, from about 300 μm to about 425 μm, from about 425 μm to about 1,000 μm, from about 425 μm to about 750 μm, from about 425 μm to about 500 μm, from about 500 μm to about 1,000 μm, from about 500 μm to about 750 μm, from about 750 μm to about 1000 μm.

If present, the film has a lower average hardness than the distal portion of the columns in some embodiments. For example, in some embodiments the film can have an average Shore A hardness of from about 5 as measured according to ASTM D2240-10 to an average Shore D hardness of about 22 as measured according to ASTM D2240-10, such as from about 5 A to about 75 A, e.g., from about 10 A to about 75 A, from about 10 A to about 70 A, from about 15 A to about 70 A, or from about 15 A to about 65 A. In preferred embodiments, the columns, and particularly the distal portions thereof, desirably do not need the presence of any abrasive particles therein for polishing performance. Thus, in some embodiments, the distal portions of at least some of the columns (e.g., all of the columns), and preferably the entire bodies of at least some of the columns (e.g., all of the columns), are substantially free of abrasive particles (e.g., less than about 2 wt. % of the distal portion of the columns, such as less than about 1 wt. %, less than about 0.1 wt. %, less than about 0.05 wt. %, less than about 0.01 wt. %, etc.) to reduce the number of defects that result during polishing. However, if desired in some embodiments, the columns can contain some abrasive particles, such as embedded in the distal portions.

It will be understood that the distal portions of the columns (with or without film as described above) can contain asperities to facilitate the removal rate of material such as metal (e.g., copper), silicon oxide, or the like on the workpiece being polished. The asperities can be formed in the distal portions of the columns in any suitable manner, such as with diamond conditioning. Advantageously, embodiments of the invention allow for use of asperities that do not significantly adversely affect the topography of the workpiece being polished, such that dishing and erosion effects are reduced or avoided, which is particularly important in advanced node applications as described herein. Desirably, in some embodiments, the asperities have a height of about 50 μm or less, e.g., from about 1 μm to about 50 μm, from about 5 μm to about 50 μm, from about 10 μm to about 45 μm, from about 15 μm to about 40 μm, or from about 15 μm to about 35 μm. In some embodiments, the asperities have a diameter of about 30 μm or less, e.g., from about 1 μm to about 30 μm, from about 5 μm to about 30 μm, from about 5 μm to about 25 μm, from about 10 μm to about 25 μm, or from about 10 μm to about 20 μm.

In accordance with preferred embodiments, the polishing pad of the invention is designed to minimize compressive shear and optimize resistance to shear bending stress (i.e., buckling stress) during operation, such that the columns control buckling stress when the polishing pad is in use. “Buckling” is the sudden failure of a column when subjected to high compressive stress. P_{cr} is the maximum axial load that a column can support when it is on the verge of buckling. For example, when P is greater than P_{cr}, the load will cause the column to buckle or deflect laterally. P_{cr} is also known as the “Euler Load.” It will be understood that failure pressure, i.e., an upper limit to the load carrying capacity, can generally be determined by measuring buckling stress. It will be understood that the critical loading condition can be expressed in terms of stress, σ_{c}=(P_{cr})/A, where A is the cross-sectional area of the column.

It will be further understood that the minimum and maximum buckling stress (G) is calculated using Euler's equation given below for a “fixed-free” type solid column (as with embodiments of the invention):

$${σ}_{c} = \frac{{π}^{3} {Er}^{4}}{16 {L}^{2}} / ( A ) ,$$

where A=area. For a circular column, A=(Π*r²),
Therefore,

$${σ}_{c} = \frac{{π}^{2} {Er}^{2}}{16 {L}^{2}}$$

for a circular column.
In the calculation, “σ_{c}” is the critical buckling stress, “E” represents the elastic modulus for the column, “r” is the radius of the column, and “L” is the length (height) of the column. In some embodiments, the elastic modulus (E) of the columns of the inventive polishing pad is from about 0.01 GPa to about 100 GPa, representing a range of materials from, e.g., elastic rubbers to aramid fiber. The modulus (E) of the columns is from about 0.01 GPa to about 50 GPa in some embodiments, such as from about 0.05 GPa to about 50 GPa, e.g., from about 0.05 GPa to about 40 GPa, from about 0.1 GPa to about 30 GPa, from about 1 GPa to about 25 GPa, or from about 1 GPa to about 20 GPa. Accordingly, in some embodiments, the critical buckling stress (σ_{c}) of the columns of the inventive polishing pad can be from about 0.1 GPa to about 50 GPa, e.g., from about 1 GPa to about 50 GPa, from about 10 GPa to about 40 GPa, from about 20 GPa to about 30 GPa, or the like.

With respect to compressive shear, it can be determined based on the equation

S=P/A,

where (S) is the compressive shear, (P) is the maximum compressive load, and (A) is the cross-sectional area. It will be understood that a typical applied load (P) during polishing is normally within a range of from about 23 kg (50 lbs) to about 81 kg (180 lbs) for a 30 cm (12 inch) diameter wafer size and a downforce of from about 10 kPa (1.5 psi) to about 34 kPa (5 psi). In some embodiments, the columns have a desired compressive shear of from about 3×10⁵ kPa (4.4×10⁴ psi) to about 1×10¹⁰ kPa (1.45×10⁹ psi), such as from about 3×10⁵ kPa (4.4×10⁴ psi) to about 1×10⁹ kPa (1.45×10⁸ psi), e.g., from about 1×10⁵ kPa (1.45×10⁴ psi) to about 1×10⁸ kPa (1.45×10⁷ psi), from about 1×10⁶ kPa (1.45×10⁵ psi) to about 1×10⁸ kPa (1.45×10⁷ psi), from about 1×10⁷ kPa (1.45×10⁶ psi) to about 1×10⁸ kPa (1.45×10⁷ psi), or from about 3×10⁷ kPa (4.4×10⁶ psi) to about 1×10⁸ kPa (1.45×10⁷ psi).

It has been found in accordance with the invention that when the columns of the inventive polishing pad are subjected to compressive loads, the columns may fail if the compressive shear exceeds the yield strength (i.e., yielding), or the columns may fail due to lateral deflection (i.e., buckling). It will be understood that yield strength can refer to the ability of a material to tolerate gradual progressive force without any permanent deformation, e.g., the stress at which a material begins to deform plastically. Yielding will happen when the stress exceeds the yield stress. In some embodiments, the ratio of critical buckling stress (σ_{c}) to compressive shear (S) (i.e., a unitless ratio since both the critical buckling stress and compressive shear are taken in pressure units such as kPa or psi) is from about 0.01 to about 50, e.g., from about 0.1 to about 20, such as from about 0.05 to about 20, from about 0.1 to about 20, from about 0.5 to about 20, or from about 0.5 to about 15.

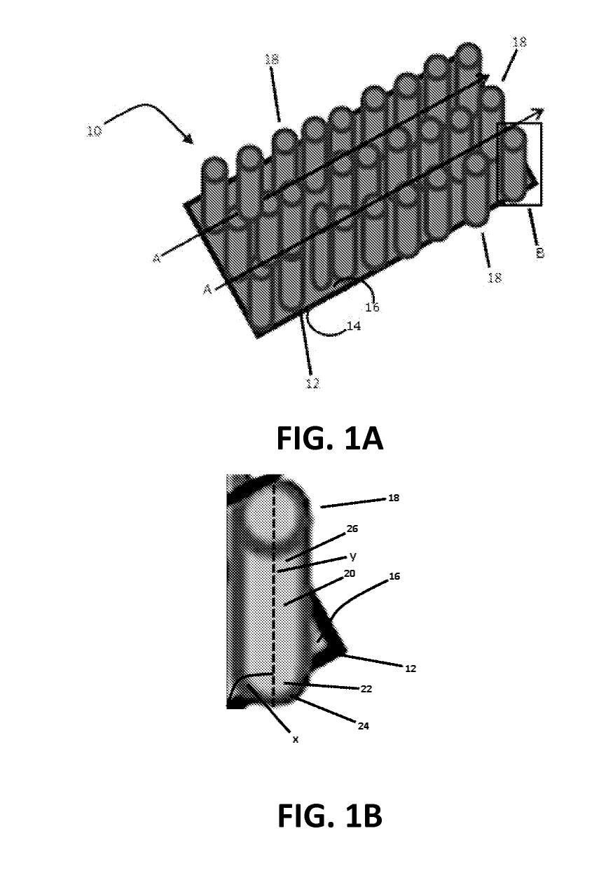

Reference is now made to the figures to depict advantageous illustrative embodiments of the invention. FIG. 1A depicts a perspective view of the polishing pad 10 comprising a substrate 12 with bottom and top surfaces 14 and 16, respectively, and a plurality of columns 18 projecting from the top surface 16 of the substrate 12 in spaced relation to each other. The spaced relation can be uniform as shown or random. The polishing composition flow path is depicted by arrows “A.”

FIG. 1B, a detail taken from rectangle B of FIG. 1A, depicts one of the columns 18. The column 18 of the chemical-mechanical polishing pad 10 has a longitudinal axis depicted by dotted line (y) and an angle, depicted by (x), from the longitudinal axis (y) to the substrate 12. In some embodiments, the angle (x) is from about 80° to about 100° (e.g., about) 90°. The column 18 has a body 20 with a portion 22 proximate to surface 16. Proximate portion 22 has an end 24 that affixes to the substrate 12 and an opposite distal portion 26 suitable for contacting a workpiece, such as a semiconductor wafer. Generally, the distal portion 26 of each of the columns 18 has a length of about 40% or less (e.g., about 30% or less, about 25% or less, or about 20% or less) of the length of the columns 18. In this respect, it has been found that having a harder (and hence stronger) proximate portion 22 of significant length (height), e.g., at least about 60% of the length of the column (such as from about 60% to about 80%, from about 65% to about 75%, about 70%, etc.), is advantageous in optimizing distribution of hardness in the polishing pad by providing greater strength for the polishing pad to rigidly adhere to the workpiece during polishing, in accordance with some embodiments. Thus, the proximate portion 22 and the substrate 12 have a higher average hardness than the average hardness of the distal portion 26.

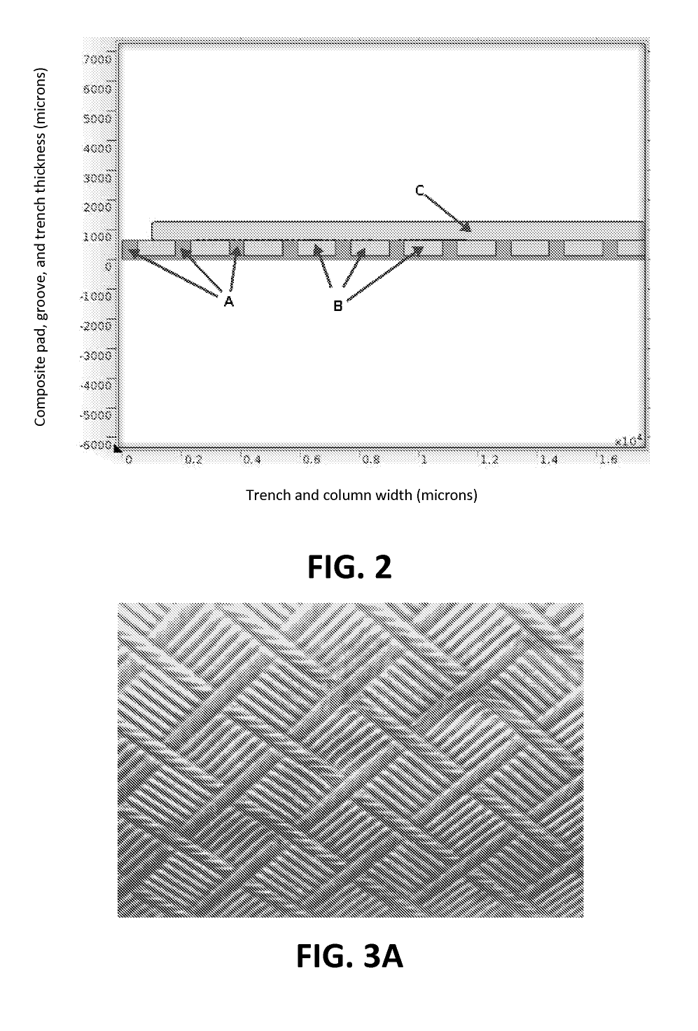

FIG. 2 illustrates an embodiment having a variable column width of a harder pad material ranging from 10 μm to 1500 μm and a variable column width of a softer pad material ranging from 10 μm to 1500 μm. In FIG. 2, “A” represents columns of the harder pad material created by cutting trenches with typical room temperature modulus ranging from 1 GPa to 10 GPa, “B” represents trench space filled-in with the softer pad material with typical room temperature modulus ranging from 0.001 GPa to 1 GPa, and “C” represents the excess pad material after filling the trenches by hot pressing, embossing, and/or thermoforming following the deposition of a thin relatively soft layer of polymer on top of the columns. Thus, FIG. 2 shows the structure of a composite pad containing harder and softer materials (relative to each other) to effectively modulate the overall pad deflection and compression by changing the ratio of the dimensions of the harder and softer materials as well as average hardness and stiffness.

While not visible in FIG. 2, such an embodiment of the invention could include grooves. In this regard, it will be understood that grooves in various arrangements can optionally be included over portions or over the entire pad surface. For example, grooves of desired type and dimension can be cut, particularly on the polishing side of the pad substrate into both harder and softer portions of the polishing pad at depth to facilitate the distribution of slurry during polishing, in some embodiments. For example, grooves can be crosshatched in an X-Y pattern, concentric, spiral, etc. Grooves can be disposed in both the harder and softer layers of pad material in the composite pad structure in embodiments that include such grooves. If included, in some embodiments, grooves can be of a similar depth as the trench depth (e.g., about 20 mils).

It will be understood that deflection indicates compression or buckling in thickness or the z-direction and is calculated using Euler's equation, described above. To illustrate, FIG. 2 depicts a composite pad structure with a column width of 50 μm (2 mils), a trench width of 125 μm (5 mils), a trench depth of 500 μm (20 mils), and a total thickness of 650 μm (25 mils). The columns A have an average width of 125 μm and modulus of 10 GPa and the trenches B have an average width of 100 μm and modulus of 0.01 GPa. As a result, the calculated deflection of the composite pad will be 0.002 μm. To further illustrate, if the width of trench B is increased to 750 μm, the deflection will now be 0.008 μm, keeping all other parameters the same. It will be understood that additional deflection values can be determined in this manner using parameter values within ranges provided herein. As the width of the softer column increases, deflection of the composite pad structure will increase, which has been found to have an adverse impact on planarization efficiency in some embodiments.

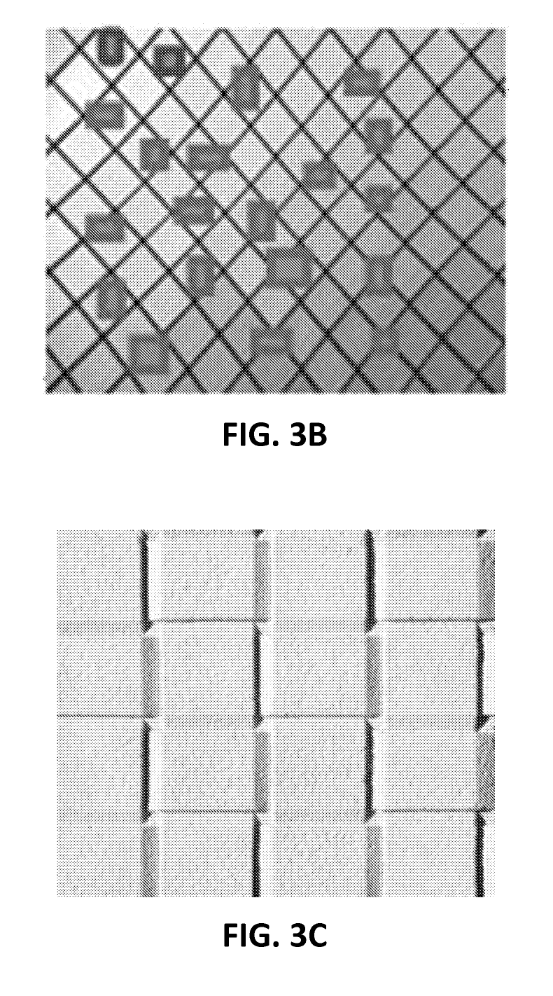

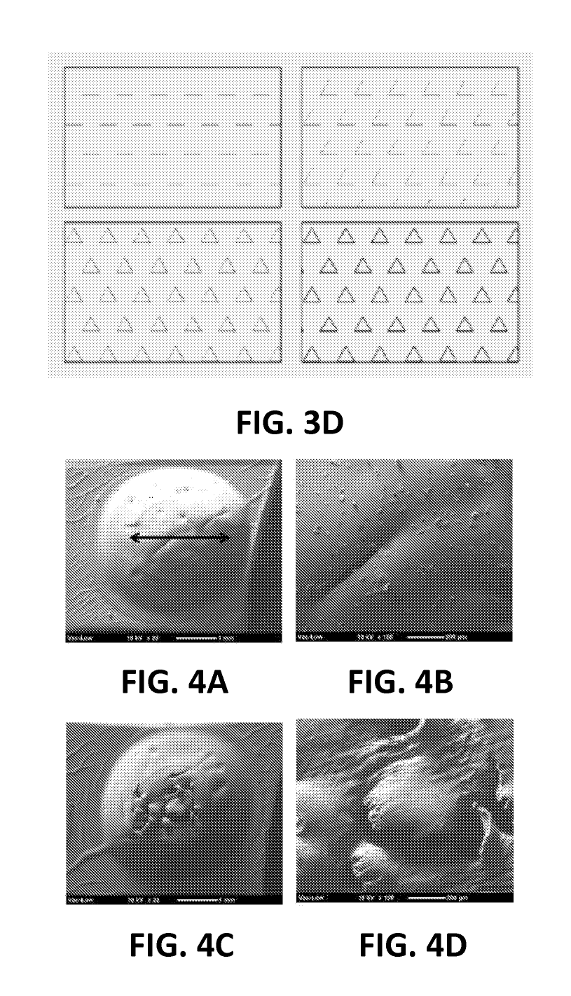

FIGS. 3A-3D are examples of column designs that can be attached to the pad substrate, e.g., PC, PET, or other pad substrate, by casting, welding, screen printing, etc., such that the columns are discrete and independent of each other to move during polishing. These exemplary designs advantageously decouple the effect of shear and torque during polishing.

In another aspect, embodiments of the invention provide a method of preparing a polishing pad. The method comprises providing a pad substrate and a plurality of columns. Each column has a body with a proximate portion having an end that affixes to the pad substrate and an opposite distal portion suitable for contacting a workpiece (such as a semiconductor wafer). The proximate portion and the pad substrate have a higher average hardness than the average hardness of the distal portion in some embodiments. The columns are attached to the pad substrate in a spaced relation (e.g., substantially uniformly or randomly). In some embodiments, the method further comprises depositing a material (e.g., continuous or discontinuous film as described herein) having an average Shore A hardness of from about 10 as measured according to ASTM D2240-10 to an average Shore D hardness of about 80 as measured according to ASTM D2240-10 on the distal portion of at least one of the columns. In some embodiments, the material is deposited by physical vapor deposition, coating, casting (e.g., by screen printing or 3D printing), laminating, calendaring, thermoforming, laser or thermal sintering, or any combination thereof

Any suitable attachment technique can be used as will be understood to one of ordinary skill in the art. For example, the attachment can be achieved by welding, gluing, calendaring, laser marking, lithography, chemical vapor deposition, physical vapor deposition, 3D printing, or any combination thereof. For example, as will be appreciated by one of ordinary skill in the art, welding can be carried out with the aid of heat and compressors to attach the columns to the pad substrate. In gluing processes, glue is used instead of heat and compressors as in stamping processes known in the art. Calendaring techniques known in the art involve passing the material through hot material and use heat compression to permanently bond the columns to the pad substrate. Laser marking techniques are also well known in the art. They typically use laser absorbing compounds to allow for targeting desired heights, width, and thickness, similar to laser grooving processes. Lithography techniques can be used in a manner similar to how semiconductors are manufactured where portions not desired for curing are masked and portions sought for curing are exposed such that the uncured portions are etched away to leave trenches in order to form columns spaced apart as desired. Chemical vapor deposition and physical vapor deposition techniques are also well known and employ the use of a mold filled with CVD or PVD material. Like a mask, the mold does not adhere to the material forming the pad such that the mold is removed.

3D printing technique is also well known in the art and employs a process of making a three-dimensional solid object of any suitable shape from a digital model. In some embodiments, 3D printing is achieved using an additive process, where successive layers of material (usually in powder form) are laid down until the layers accumulate to form an object of any desired shape or form. 3D printing can be accomplished with computer aided design (CAD).

Another way to attach the desired column structure is by the process of laser-welding in some embodiments. The laser-welding of plastics consists of bonding of thermoplastics under heat and pressure. The bonded surfaces must be in the thermoplastic state. Plastics can be laser-welded with or without laser absorbing additives, such as carbon black, titanium dioxide (TiO₂), other metal oxides, or special laser absorbing dyes. Laser-welding is usually performed in the overlap process. Two join partners are used. The upper join partner is a laser-transparent thermoplastic, selected according to the laser wavelength, which, upon the passage of the laser beam, heats up very little if at all. To produce a weld seam, the second join partner must absorb the laser radiation. The absorbing medium can be, for example, a laser-transparent thermoplastic doped with the aforementioned laser additives. When this substance absorbs energy it begins to fuse and transmits its energy to the upper join partner. Thus, under the application of heat and pressure a column of the desired thermoplastic polymer of desired dimensions (transmitting polymer) can be bonded to a desired substrate (absorbing polymer).

The inventive polishing pad is not limited by the method of manufacture and other means (e.g., mechanical) can be utilized to form the polishing pad in accordance with embodiments of the invention.

Thus, in some embodiments, the columns are attached to the pad substrate by the use of adhesive (e.g., optionally into a trench formed in the pad substrate). Any suitable adhesive can be employed. Preferred adhesives are water-based such that the water is driven off during the curing process to enhance bonding. For example, the adhesive can be in the form of liquid, solid, slurry, paste (aqueous or non-aqueous), or any combination thereof. In some embodiments, the adhesive is an acrylic and/or UV cured adhesive. For example, the adhesive can be a UV cured adhesive, such as acrylic, epoxy, polyester, silicone, cyanoacrylate, or vinyl ether. Examples of such suitable adhesives are available from Panacol-Elosol GmbH (Steinbach, Germany) (see, e.g., VITRALIT™ products) and Schwarzkopf & Henkel GmbH (Dusseldorf, Germany). In some embodiments, the ultraviolet-curable acrylic adhesive is UV-Curable Adhesive LC-3200 commercially available from 3M, St. Paul, Minn.

The invention further provides a method of polishing a workpiece, e.g., a substrate to be polished, such as a semiconductor wafer, comprising (i) contacting the workpiece with the inventive polishing pad, and (ii) moving the polishing pad relative to the workpiece to abrade the workpiece and thereby polish the workpiece. Typically a chemical-mechanical polishing composition will be utilized in the polishing of a workpiece with the inventive polishing pad, such that the inventive method of polishing a workpiece, e.g., a substrate to be polished, such as a semiconductor wafer, further comprises providing a chemical-mechanical polishing composition between the polishing pad and the workpiece, contacting the workpiece with the polishing pad with the polishing composition therebetween, and moving the polishing pad relative to the workpiece with the polishing composition therebetween to abrade the workpiece and thereby polish the workpiece.

Advantageously, in some embodiments, the inventive polishing method substantially excludes the need for any diamond conditioning or brush conditioning after the polishing pad has been used because of, for example, complications from viscoelastic flow. In this regard, during the polishing process, the polishing pad temperature can increase (e.g., to about 80° C. to 90° C.). Once the temperature exceeds the glass transition temperature of the pad material, viscoelastic flow is induced. In this respect, in conventional polishing pad systems, material normally tends to be removed from the workpiece being polished and become affixed to the polishing pad after exposure to viscoelastic flow. In addition, asperities from conventional polishing pads can become lost over time as the pad is exposed to viscoelastic flow. In order to refresh the polishing pad in response to these phenomena, brush type conditioners (e.g., polyvinyl alcohol based cross-linked brushes) or diamond conditioners are used in conventional systems. The design of the inventive polishing pad advantageously avoids the need for any such brush or diamond conditioning in accordance with some embodiments after the polishing pad has been in use. For example, the reduced downforce described herein extends the longevity of the asperities such that diamond or brush conditioning can be avoided in some embodiments.

The polishing pad of the invention is particularly suited for use in conjunction with a chemical-mechanical polishing (CMP) apparatus. Typically, the apparatus comprises a platen, which, when in use, is in motion and has a velocity that results from orbital, linear, or circular motion (i.e., rotates), a polishing pad of the invention in contact with the platen and moving with the platen when in motion, and a carrier that holds a substrate to be polished by contacting and moving relative to the surface of the polishing pad intended to contact a substrate to be polished. The polishing of the substrate takes place by the substrate being placed in contact with the polishing pad and then the polishing pad moving relative to the substrate, typically with a polishing composition therebetween, so as to abrade at least a portion of the substrate to polish the substrate. The CMP apparatus can be any suitable CMP apparatus, many of which are known in the art. The polishing pad of the invention also can be used with linear polishing tools.

In another aspect, the invention provides a chemical-mechanical polishing apparatus comprising (a) a platen that rotates; (b) a polishing pad in accordance with embodiments described herein and disposed on the platen; and (c) a carrier that holds a workpiece to be polished by contacting the rotating polishing pad. In some embodiments, the CMP apparatus further comprises (d) means for delivering a chemical-mechanical polishing composition between the polishing pad and the workpiece. For example, in some embodiments, the means for delivering the chemical-mechanical polishing composition can include, for example, a pump and flow metering system.

The polishing pad described herein is suitable for use in polishing any suitable substrate, e.g., memory storage devices, semiconductor substrates, and glass substrates. Suitable substrates for polishing with the polishing pad include memory disks, rigid disks, magnetic heads, MEMS devices, semiconductor wafers, field emission displays, and other microelectronic substrates, especially substrates comprising insulating layers (e.g., silicon dioxide, silicon nitride, or low (k) dielectric materials) and/or metal-containing layers (e.g., copper, tantalum, tungsten, aluminum, nickel, titanium, platinum, ruthenium, rhodium, iridium, or other noble metals).

The following examples further illustrate the invention but, of course, should not be construed as in any way limiting its scope.

### Example 1

This example demonstrates the use of a printing technique to prepare polishing pads in accordance with embodiments of the invention.

To prepare polishing pads having a substrate and columns projecting therefrom, a plurality of columns composed of aqueous polyurethane and/or aqueous polyacrylic dispersion in paste form that also contains cross-linker such as DESMODUR™ N3900 from Bayer was applied to a rotary screen having the desired pattern and column height, which was cast directly onto an 81 cm (32 inch) wide series of substrates. The substrates were composed of polycarbonate (PC) laminate, prepared with double coated polyester film tape 442F commercially available from 3M (St. Paul, Minn.) and polyethylene terephthalate (PET). PC and PET both were either purchased from Tekra Inc. (New Berlin, Wis.) or Piedmont Plastics (Bolingbrook, Ill.).

Three different formulations for pre-polymer paste commercially available as PERFORMAX™ 9235 and PRINT RITE™ (Lubrizol Corporation, Wickliffe, Ohio), and Bayhydrol (Bayer Material Science, Pittsburgh, Pa.) were used to cast the columns to the PC/442 and PET substrates. The pre-polymer pastes are chemically characterized by aqueous polyurethane dispersion based on any of the following: aliphatic polyether, aromatic polyester urethane resin, aliphatic polycarbonate urethane resin, hydroxyl functional polyacrylic resin, or urethane-acrylate dispersion. PERFORMAX™ pre-polymer is a high solid content aqueous polyurethane dispersant while PRINTRITE™ is an aqueous acrylic polymer dispersant and Bayhydrol is an aqueous anionic polyurethane dispersant based on aliphatic polyester urethane resin. Other suitable dispersants that can be used are: CARBOCURE™, CARBOSET™, CARBOTAC™, CARBOBOND™, CARBOSPERSE™, all from Lubrizol, and IMPRANIL™ from Bayer.

It was found that the viscosity and proper wetting and spreading of the paste onto the casting substrate were important parameters in preventing smearing, which renders the columns indistinct and produces a continuous film. Paste viscosity from about 20 centipoise (“cps”) to about 60 cps was found to be desirable. In some embodiments, higher viscosities within the range are more effective (e.g., from about 10 cps to about 5000 cps, such as from about 10 cps to about 2500 cps, from about 20 cps to about 2000 cps, or from about 20 cps to about 1000 cps). To increase viscosity, viscosity modifiers such as clays, CARBOPOL™ and ASTERIC™ from Lubrizol etc. can be added to the formulation as one of ordinary skill in the art will appreciate. It was also found that a pH of about 4.5 is desirable. However, a pH of about 8 or less can be used, such as about 7 or less, about 6 or less, or about 5 or less (e.g., with a lower limit of about 2.0), in some embodiments.

The columns were cast using the aforementioned pre-polymer paste onto the PC/442 or PET substrates using rotary textile printing machine called Pegusus EVO and a rotary screens commercially identified as ROTAMESH™, which is a non-woven electroformed mesh made of nickel, available from SPG prints (Boxmeer, Netherlands). It was found that a desired rotary screen was characterized by mesh/linear inch from 75 to 405, such as the aforementioned screen thickness ranges from 50 microns to 150 microns, hole diameter from 24 microns to 214 microns, and percent of open area from 8% to 40% rotary screens.

After casting, the resulting precursor was cured to form the polishing pad. A curing oven was utilized for this purpose. The oven has three three-meter (ten-foot) sections. The first section was set at 120° C., the middle section was set at 140° C., and the exit section was set at 160° C. It was found that a residence time of about two minutes was effective to complete the curing process. Other residence times of from about one minute to about twenty minutes, such as from about one minute to about fifteen minutes, from about one minute to about ten minutes, from about one minute to about five minutes, from about one minute to about three minutes, from about 90 seconds to about 150 seconds, from about 90 seconds to about 120 seconds, or from about 105 seconds to about 135 seconds can be used in some embodiments.

It was found that adhesion of the columns to the PC/442 substrate was excellent. The PET substrate was not as conducive for adhesion to the columns without treatment. However, it was found that corona treated PET exhibited improved adhesion. In addition, it was found that an ultraviolet-curable acrylic adhesive (commercially available as UV-Curable Adhesive LC-3200 from 3M, St. Paul, Minn.) can be used to improve adhesion (e.g., with column heights of about 0.25 mm (10 mils) to about 0.76 mm (30 mils)).

Two of the resulting polishing pads prepared with the PC/442 substrate had the following column definition: 2 mm column diameter, 0.46-0.56 mm (18-22 mils) column height, and 3-5 mm column pitch, and were further tested for the following properties set forth in Table 1 below. “Density, g/cc” refers to the bulk density of the porous column. “% P” refers to percent porosity, which is the ratio of the densities of a porous column to that of a non-porous column. “Column hardness” refers to the average hardness of the distal portion of the columns. “% C @ 34.5 kPa (5 psi)” refers to percent compressibility of the porous column measured using an Ames meter as described in U.S. Pat. No. 6,899,598.

TABLE 1

| Pad | Density, | | Column | % C @ 34.5 kPa |
|---|---|---|---|---|
| number | g/cc | % P | hardness | (5 psi) |
| 1A | 1.146 | 11% | 88A | 4.7 |
| 1B | 1.152 | 9% | 89A | 3.8 |

FIGS. 4A-4D present scanning electron micrographs at 24 times magnification (FIGS. 4A and 4C) and 100 times magnification (FIGS. 4B and 4D) of an additional polishing pad made by the foregoing technique with a PC/442 substrate, both before (FIGS. 4A and 4B) and after (FIGS. 4C and 4D) polishing a tungsten metal semiconductor wafer. The polishing pad 1A had the following column definition: 1 mm column diameter, 0.706 mm (18 mils) avg. column height, 2.5 mm pitch, 10% void volume, and 25 column/linear inch. The polishing was carried out with a polishing composition commercially available as WIN® W7500 series slurry (Cabot Microelectronics, Aurora, Ill.). The SEM images show that “as received” pad sample has smooth column surface but as the polishing process starts and thus removes the top material layer from the column it exposes the porous structure underneath the column structure. FIGS. 4A and 4B are pre-polished SEMs for pad 1A at two different magnifications (24× and 100×). FIGS. 4C and 4D are SEMs for the same pad in FIGS. 4A and 4B at 24× and 100×, respectively, but post-polished.

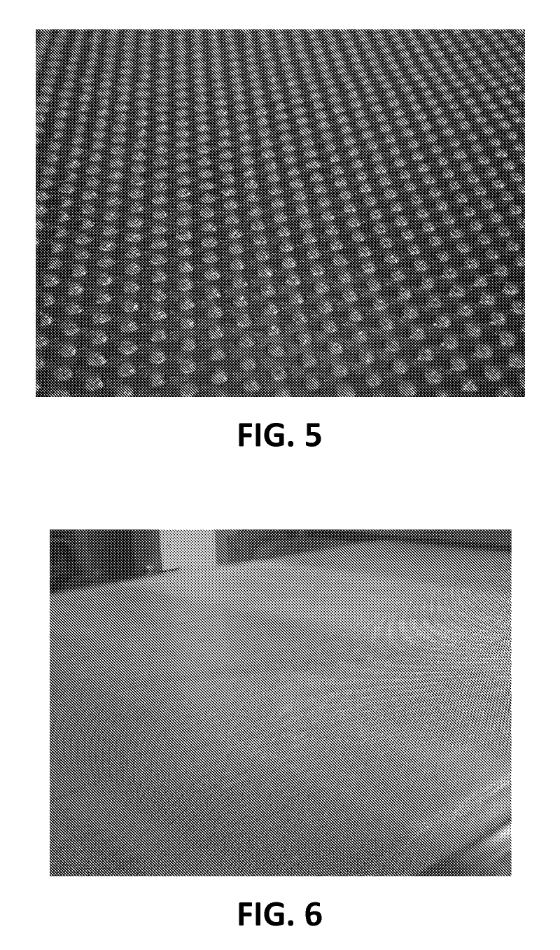

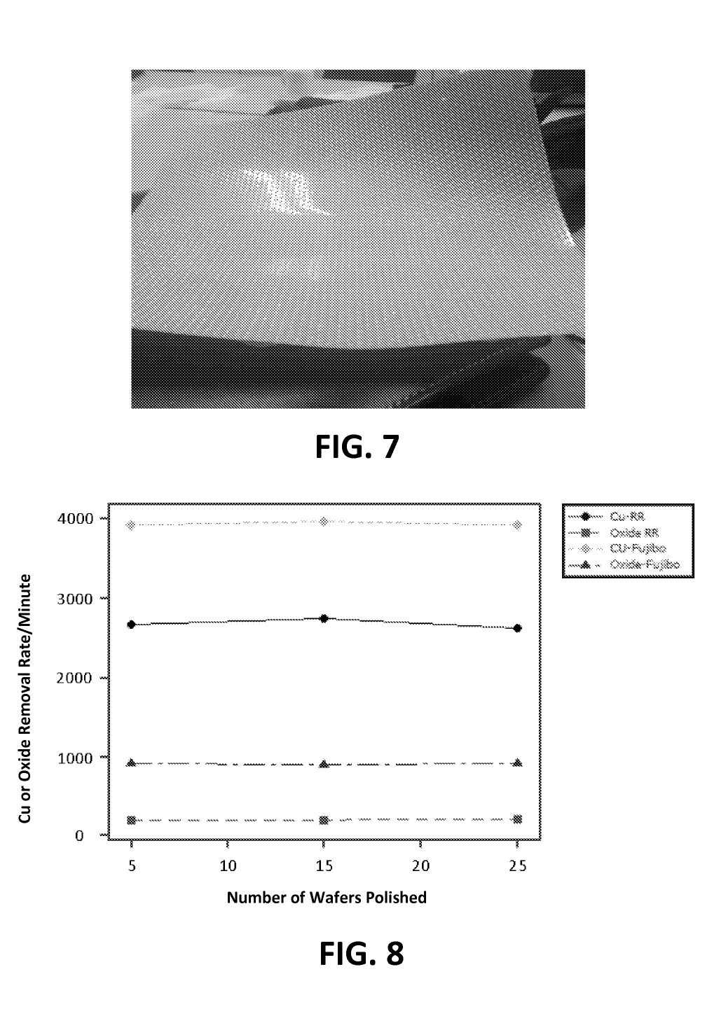

In addition, FIGS. 5-7 are photographs illustrating additional polishing pads with different patterned arrangements for the columns projecting from the substrate. In particular, FIG. 5 is a photograph of a 0.05 mm (2 mils) PET film with following column definition: 2 mm column diameter, 1.06 mm (27 mils) column height, 5 mm pitch, 40% void volume, and 5 column/linear inch. FIG. 6 is a photograph depicting a patterned arrangement of finer columns on PC/442 with the following column definition: 0.2 mm column diameter, 0.865 mm (22 mils) column height, 1.5 mm pitch, 14% void volume, and 18 column/linear inch. FIG. 7 is a photograph depicting a patterned arrangement of larger columns on PC/442 with the following column definition: 2.75 mm column diameter, 0.315 mm (8 mils) column height, 15 mm pitch, 12% void volume, and 9 column/linear inch. As seen from FIGS. 5-7, the column definition such as height and spacing and diameter of the column can be controlled by controlling the pre-polymer paste chemistry, pH and viscosity, as well as the ROTAMESH™ size.

### Example 2

This example demonstrates the use of a laser engraving technique to prepare polishing pads in accordance with embodiments of the invention.

A polishing pad was prepared having a plurality of columns composed of acrylonitrile butadiene styrene (ABS). It will be understood that the columns could also be composed of thermoplastic polyurethane (TPU), nylon, polybutylene terephthalate (PBT), acetal polymers, etc. The columns were cast directly onto a 25 cm (10 inch) wide substrate. The polymers have laser absorbing additive (0.3% carbon black). The polishing pad was formed from laser engraving conducted on HSE Laser System 100, commercially available from Kern Lasers Inc. (Wadena, Minn.). A carbon dioxide (CO₂) laser was used. The laser was operated at a power of 100 watts, pulse frequency of 600 mm/sec, and a laser focus spot size from 25 to 500 microns depending on the height desired. The resulting polishing pad had an average column height of about 400 microns and an average diameter of about 25 microns.

The actual measured column height was performed by confocal microscopy with a distribution as follows: 55% of the columns had an average diameter of about 25-30 microns, 15% had a diameter of 50 microns, with the remaining columns having a diameter between 10 and 24 μm; over 80% of the columns had heights between 300 and 400 microns, with a target height of 400 microns.

Using the laser engraving technique, it was found that the resulting polishing pad exhibited columnar structure of desired height, modulus, and hardness on which a thin soft polyurethane or elastomeric polishing layer can be cast to create a polishing pad that will exhibit high polishing material removal rate (RR), low wafer scratch count, and good planarization efficiency (PE).

### Example 3

This example illustrates the beneficial effect of using a polishing pad in accordance with embodiments of the invention on removal rates of copper and silicon oxide, respectively, on blanket semiconductor wafers containing copper or silicon oxide. The results were compared with the removal rates demonstrated by a conventional pad commercially identified as Fujibo H7000, available from Marubeni America Corp. (Sunnyvale, Calif.).

In particular, blanket wafers (i.e., without any patterns) containing copper were polished using a polishing composition commercially available as C8910 from Cabot Microelectronics (Aurora, Ill.), having the following formulation: 0 wt. % abrasive, 1.5 wt. % hydrogen peroxide (H₂O₂), pH=4, where a 1:9 dilution was used. Blanket wafers containing silicon oxide were polished using a polishing composition commercially available as W7573-M87 from Cabot Microelectronics (Aurora, Ill.), having the following formulation: 3 wt. % colloidal silica abrasive, 2 wt. % H₂O₂, pH=2.6, where a 1:1 dilution was used.

The polishing was carried out with a polishing pad prepared in accordance with pad 1A of Example 1, which was die-cut to form a 30 inch (76 cm) circle, with the results shown in FIG. 8 as “CU-RR” and “Oxide RR”. For comparison purposes, the copper blanket wafers and silicon oxide blanket wafers as described above were also polished with the Fujibo H7000 polishing pad.

The substrates were polished on a REFLEXION™ CMP apparatus using TITAN PROFILER™ carrier head, both of which are commercially available from Applied Materials, Inc. (Santa Clara, Calif.). The polishing parameters were as follows: 20.7 kPa (3 psi) downforce (“DF”), 2.7 kg (6 lbs) conditioner DF, 150 ml/min slurry flow rate, and 103 rpm platen speed.

Following polishing, the removal rate of copper and silicon oxide, respectively, was determined in Å/60 seconds. The results are illustrated in FIG. 8, which is a plot of average Cu and oxide removal rate amount in 60 seconds (y-axis) as a function of the number of wafers polished (x-axis).

These results demonstrate that the use of a polishing pad in accordance with embodiments of the invention are effective for polishing substrates such as semiconductor wafers that contain copper and silicon oxide. As seen in FIG. 8, although the removal rates for both copper and silicon oxide using the inventive polishing pad were not as high as the removal rates resulting from the Fujibo H7000 polishing pad, they were comparably acceptable and efficient. As such, the inventive polishing pad is suitably effective for removing copper and silicon oxide. It will be understood that the removal rates demonstrated by the inventive polishing pad are particularly acceptable when used with advanced node semiconductor applications (e.g., 28 nm or less, 20 nm or less, 14 nm or less, etc.). In addition, it can be seen from FIG. 8 that the removal rates for copper are higher than for silicon oxide, which is desirable since silicon oxide removal is generally expected to be lower than copper removal.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A polishing pad for chemical-mechanical polishing comprising a substrate with two opposing surfaces and a plurality of columns projecting from at least one of the surfaces of the substrate in spaced relation to each other, wherein each of the columns has a body with a proximate portion having an end that affixes to the substrate and an opposite distal portion suitable for contacting a workpiece, and wherein the substrate has a higher average hardness than the average hardness of the distal portion.

2. The polishing pad of claim 1, wherein the columns are spaced substantially uniformly.

3. The polishing pad of claim 1, wherein the pad includes from about 4 columns to about 2,500 columns per cm² of the substrate surface.

4. The polishing pad of claim 1, wherein the substrate is substantially planar, each of the columns has a longitudinal axis, and an angle (x) from the longitudinal axis to the substrate is from about 80° to about 100°.

5. The polishing pad of claim 1, wherein the angle (x) is about 90°.

6. The polishing pad of claim 1, wherein the thickness of the substrate is from about 0.025 cm to about 1 cm.

7. The polishing pad of claim 1, wherein the columns have an average height of from about 125 μm to about 1500 μm.

8. The polishing pad of claim 1, wherein the average diameter of the columns is from about 3 μm to about 1 mm.

9. The polishing pad of claim 1, wherein the aspect ratio of the thickness of the pad to the diameter of the pad is at least 1.

10. The polishing pad of claim 1, wherein the distal portions of the columns have an average Shore A hardness of from about 10 to about 90 as measured according to ASTM D2240-10, and the proximate portion of at least some of the columns have an average Shore D hardness of from about 10 to about 90 as measured according to ASTM D2240-10.

11. The polishing pad of claim 1, wherein at least one column body has varying average hardness ranging from a Shore D hardness of about 20 as measured according to ASTM D2240-10 to a Rockwell hardness of about 150 M as measured according to ASTM D785-08.

12. The polishing pad of claim 1, wherein the varying hardness is in a random pattern.

13. The polishing pad of claim 1, wherein the varying hardness is in a pre-selected pattern.

14. The polishing pad of claim 1, wherein at least one column body comprises a film covering the distal portion, and wherein the film has an average Shore A hardness of from about 10 as measured according to ASTM D2240-10 to an average Shore D hardness of about 20 as measured according to ASTM D2240-10.

15. The polishing pad of claim 14, wherein the film has pores.

16. The polishing pad of claim 14, wherein the film is non-porous.

17. The polishing pad of claim 14, wherein the film has holes defined therein.

18. The polishing pad of claim 14, wherein the film has a thickness of from about 25 μm to about 1000 μm.

19. The polishing pad of claim 1, wherein the distal portion of each of the columns has a length of about 30% or less of the length of the columns.

20. The polishing pad of claim 1, wherein the distal portions of the columns comprise pores.

21. The polishing pad of claim 1, wherein the distal portions of the columns have an average void volume of from about 5% to about 90% of the total volume of the distal portion.

22. The polishing pad of claim 1, wherein the pores in the distal portions of the columns have an average diameter of about 150 microns or less.

23. The polishing pad of claim 1, wherein the columns are cylindrical.

24. The polishing pad of claim 1, wherein the columns have a longitudinal axis and an axis transverse to the longitudinal axis, and wherein a cross-section of a plane along the transverse axis of the columns forms a polygonal perimeter shape.

25. The polishing pad of claim 1, wherein the substrate has an average Shore D hardness of from about 20 as measured according to ASTM D2240-10 to an average Rockwell hardness of about 150 M as measured according to ASTM D785-08.

26. The polishing pad of claim 1, wherein the substrate is free of grooves.

27. The polishing pad of claim 1, wherein the substrate defines at least one trench therein to receive the proximate end of at least one column.

28. The polishing pad of claim 27, wherein the trenches contain material having an average hardness that is lower than the average hardness of the pad substrate.

29. The polishing pad of claim 28, wherein the material contained in the trenches has an average Shore A hardness of from about 10 to about 95 as measured according to ASTM D2240-10.

30. The polishing pad of claim 1, wherein the pad substrate is formed of one layer.

31. The polishing pad of claim 1, wherein the pad substrate is formed of at least two layers.

32. The polishing pad of claim 31, wherein the pad substrate contains a base layer and an overlying layer adjacent to the columns, and wherein the base layer has an average hardness that is higher than the average hardness of the overlying layer.

33. The polishing pad of claim 31, wherein the pad substrate contains a base layer and an overlying layer adjacent to the columns, and wherein the base layer has an average hardness that is lower than the average hardness of the overlying layer.
